(19) United States
(12) Patent Application Publication
(10) Pub. No.: US 2026/0085414 A1
(43) Pub. Date: Mar. 26, 2026

(54) METHOD AND APPARATUS FOR FORMING METAL SILICIDE LAYER ON SUBSTRATE

(71) Applicant: Tokyo Electron Limited, Minato-ku, Tokyo (JP)

(72) Inventors: Tatsuya SANO, Nirasaki City (JP); Liang Kai ONG, Paya Lebar Quarter (SG)

(21) Appl. No.: 19/304,635

(22) Filed: Aug. 20, 2025

(30) Foreign Application Priority Data
Aug. 27, 2024 (JP) 2024-145833

(51) Int. Cl. C23C 16/455; C23C 16/02; C23C 16/42; C23C 16/52

(52) U.S. Cl. CPC C23C 16/45527; C23C 16/0209; C23C 16/42; C23C 16/45544; C23C 16/52

(57) ABSTRACT

A method for forming a metal silicide layer on a substrate, the method including: heating the substrate from which a silicon layer is exposed to a temperature in a range of 490 degrees C. or higher and 600 degrees C. or lower; preliminarily supplying a raw material gas, which is a metal halide gas containing a metal that constitutes the metal silicide and a halogen, to the heated substrate; and forming a layer of the metal on a surface of the silicon layer by alternately and repeatedly supplying the raw material gas and a reactive gas, which reacts with the metal halide to obtain the metal, to the substrate to which the raw material gas has been preliminarily supplied, wherein the metal silicide layer is formed by diffusing silicon from the silicon layer into the layer of the metal.

### CROSS-REFERENCE TO RELATED APPLICATION

This application is based upon and claims the benefit of priority from Japanese Patent Application No. 2024-145833, filed on Aug. 27, 2024, the entire contents of which are incorporated herein by reference.

### TECHNICAL FIELD

The present disclosure relates to a method and apparatus for forming a metal silicide layer on a substrate.

### BACKGROUND

In a semiconductor device manufacturing process, a process of forming various layers such as a metal layer and an insulating layer on a semiconductor wafer (hereinafter also referred to as a “wafer”), which is a substrate, is performed. For example, a method for selectively depositing a MoSix material, which is a metal silicide, on a substrate is disclosed in Patent Document 1. In this method, a heated substrate is exposed to first and second doses of MoF₆ precursor and Si₂H₆ precursor in continuous cycles, and then exposed to a third dose of Si₂H₆ precursor. However, Patent Document 1 does not disclose a method that takes into account the influence on other layers when a raw material gas containing halogen is used as a raw material of metal silicide.

### PRIOR ART DOCUMENT

### Patent Document

Patent Document 1: Japanese Laid-open Publication No. 2020-522138

### SUMMARY

According to an embodiment of the present disclosure, there is provided a method for forming a metal silicide layer on a substrate, the method including: heating the substrate from which a silicon layer is exposed to a temperature in a range of 490 degrees C. or higher and 600 degrees C. or lower; preliminarily supplying a raw material gas, which is a metal halide gas containing a metal that constitutes the metal silicide and a halogen, to the heated substrate; and forming a layer of the metal on a surface of the silicon layer by alternately and repeatedly supplying the raw material gas and a reactive gas, which reacts with the metal halide to obtain the metal, to the substrate to which the raw material gas has been preliminarily supplied, wherein the metal silicide layer is formed by diffusing silicon from the silicon layer into the layer of the metal.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a vertical sectional side view showing an example of a configuration of a processing apparatus which is an apparatus for forming a molybdenum silicide layer.

FIG. 2 is a schematic diagram showing a state in which a molybdenum layer is formed before it becomes a molybdenum silicide layer.

FIGS. 3A to 3C are reaction model diagrams showing states of a wafer surface for the formation of a molybdenum layer.

FIG. 4 is a graph showing a relationship between supply time of MoCl₅ and amount of Mo removed.

FIGS. 5A to 5C are time charts showing a supply sequence of various gases for the formation of a molybdenum layer according to a first embodiment.

FIGS. 6A to 6C are reaction model diagrams showing states of a wafer surface according to the first embodiment.

FIGS. 7A to 7C are time charts showing a supply sequence of various gases for the formation of a molybdenum layer according to a second embodiment.

FIG. 8 is a reaction model diagram showing a state of a wafer surface according to the second embodiment.

FIGS. 9A and 9B are electron microscopic photographs of a molybdenum layer formed at a wafer heating temperature of 550 degrees C.

FIGS. 10A and 10B are electron microscopic photographs of a molybdenum layer formed at a wafer heating temperature of 450 degrees C.

FIG. 11 shows results of XRD analysis of molybdenum silicide layers obtained from respective experiments.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### <Processing Apparatus>

The present disclosure pertains to a method of forming a metal silicide layer by, forming a metal layer on a silicon layer 51 exposed on a wafer W using a metal halide gas, and then diffusing silicon toward the metal layer. An example in which a molybdenum (Mo) layer is formed as a metal layer will be described below. The Mo layer is formed by using a molybdenum pentachloride (MoCl₅) gas, which is a raw material gas containing a metal halide, and a hydrogen (H₂) gas, which is a reactive gas that reacts with MoCl₅ to obtain Mo.

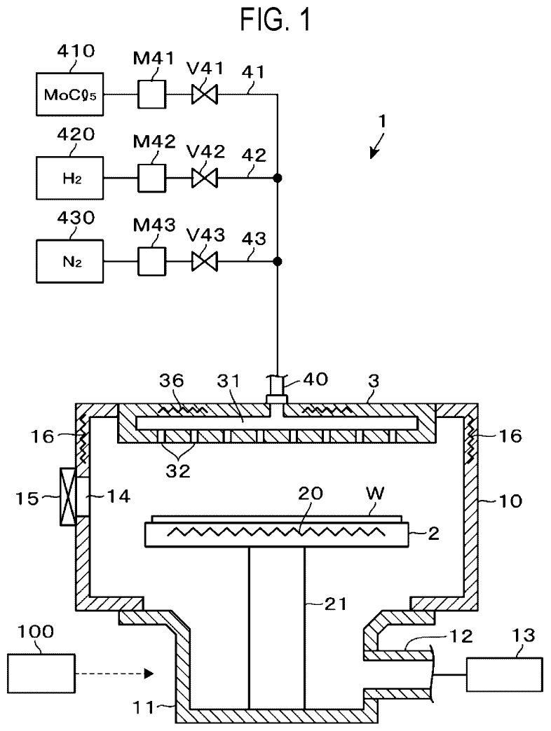

FIG. 1 is a vertical sectional side view of a processing apparatus 1 according to the present embodiment. The processing apparatus 1 is configured as an apparatus for forming a Mo layer 6 by a thermal ALD (Atomic Layer Deposition) method in which MoCl₅ gas and H₂ gas are alternately and repeatedly supplied to a surface of a heated wafer W. Compared to using plasma or other means for activating a raw material gas or a reactive gas, the thermal ALD method has small anisotropy in the direction of movement of active species, allowing the active species to move freely in both horizontal direction and the vertical direction. Therefore, the thermal ALD method is less susceptible to structural constraints of a semiconductor device, and can form the Mo layer 6 even on a semiconductor device having a complex structure or a recess with a high aspect ratio.

The processing apparatus 1 includes a substantially cylindrical processing container 10 made of a metal that is resistant to corrosion by chlorine. For example, a cylindrical exhaust chamber 11 protruding downward is formed at a center of a bottom surface of the processing container 10. An exhaust path 12 is connected to a side surface of the exhaust chamber 11. An exhauster 13 including a pressure regulation valve, for example, a butterfly valve, is connected to the exhaust path 12. The exhauster 13 is configured to be able to evacuate the inside of the processing container 10 to a preset vacuum pressure.

A loading/unloading port 14 for loading and unloading the wafer W between the processing container 10 and a vacuum transfer chamber (not shown) is formed on a side surface of the processing container 10. The loading/unloading port 14 is configured to be open and closed by a gate valve 15. Furthermore, a heater 16 for adjusting a temperature inside the processing container 10 is embedded in a wall that constitutes the processing container 10.

A stage 2 for holding the wafer W substantially horizontally is provided inside the processing container 10. The stage 2 is supported by a support 21 extending from a bottom of the exhaust chamber 11. A heater 20 is embedded in the stage 2, and the wafer W can be heated to a preset temperature. The stage 2 is provided with lift pins (not shown) for holding, raising and lowering the wafer W. The wafer W can be transferred between the stage 2 and an external transfer mechanism (not shown) by raising and lowering the lift pins.

A flat, disk-shaped showerhead 3 is attached to a ceiling surface of the processing container 10 to supply a processing gas toward the wafer W. A diffusion chamber 31 for diffusing gas is formed inside the showerhead 3, and a number of discharge holes 32 for discharging gas toward the wafer W are dispersed in a bottom surface of the showerhead 3. In addition, for example, a heater 36 is embedded in an upper surface of the showerhead 3.

A downstream end of a gas supply path 40 is connected to the diffusion chamber 31 of the shower head 3. Supply flow paths 41 and 42 for MoCl₅ gas, which is a raw material gas, and H₂ gas, which is a reactive gas, and a supply flow path 43 for a nitrogen (N₂) gas, which is a purge gas, join on an upstream side of the gas supply path 40.

A MoCl₅ gas source 410 is connected to an upstream end of the MoCl₅ gas supply flow path 41, and a flow rate adjuster M41 and a valve V41 are installed sequentially from the upstream side. The MoCl₅ gas source 410 includes a raw material container containing solid MoCl₅, and the MoCl₅, which is heated and sublimated in the raw material container, is picked up by a carrier gas such as a N₂ gas or the like. Then, a mixed gas of MoCl₅ and N₂ is sent to the supply flow path 41 as a raw material gas. A H₂ gas source 420 is connected to an upstream end of the H₂ gas supply flow path 42, and a flow rate adjuster M42 and a valve V42 are installed sequentially from the upstream side. A N₂ gas source 430 is connected to an upstream end of the N₂ gas supply flow path 43, and a flow rate adjuster M43 and a valve V43 are installed sequentially from the upstream side.

In the present example, a raw material gas supply is composed of the MoCl₅ gas source 410, the MoCl₅ gas supply flow path 41, and the gas supply path 40. A reactive gas supply is composed of the H₂ gas source 420, the H₂ gas supply flow path 42, and the gas supply path 40.

The processing apparatus 1 having the above-mentioned configuration includes a controller 100 as shown in FIG. 1. The controller 100 is composed of a computer including a storage storing a program, a memory, and a CPU. The program includes commands (steps) which are combined to execute a process of forming the Mo layer 6. These commands execute such a process by outputting control signals from the controller 100 to respective parts of the processing apparatus 1 and controlling supply and cut-off of each gas and heating of the wafer W. The program is stored in the storage of the computer, such as a flexible disk, a compact disk, a hard disk, a MO disk (magneto-optical disk), a non-volatile memory, or the like, and is read from the storage and installed in the controller 100.

### <Problems in the Formation of Mo Layer 6>

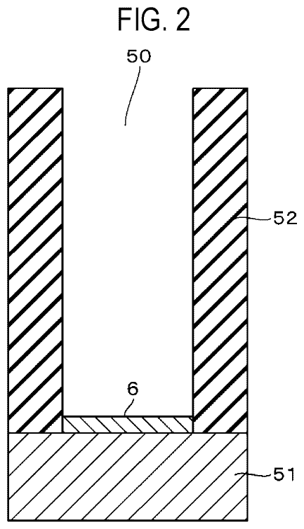

Problems in the formation of a Mo layer by a thermal ALD method using the above-described processing apparatus 1 will be described below. FIG. 2 shows a schematic structure of a region near the surface of the wafer W on which a Mo layer is formed using the processing apparatus 1. The surface of the wafer W is covered with a silicon oxide layer (SiO layer 52), which is an insulating layer. A recess 50 is formed in the SiO layer 52. At a bottom end of the recess 50, a silicon layer 51, which is an upper surface region of the silicon substrate that constitutes a body of the wafer W, is exposed.

For the wafer W having the above-described structure, the processing apparatus 1 forms a Mo layer 6 on a surface of the silicon layer 51 exposed in the recess 50. It is understood by the inventors that in a case of thermal ALD using MoCl₅ gas and H₂ gas, the Mo layer 6 can be formed under conditions in which the wafer W is heated to a temperature within a range of, for example, 400 degrees C. to 600 degrees C. However, it has been found that when the Mo layer 6 is formed, different problems arise depending on the heating temperature range of the wafer W.

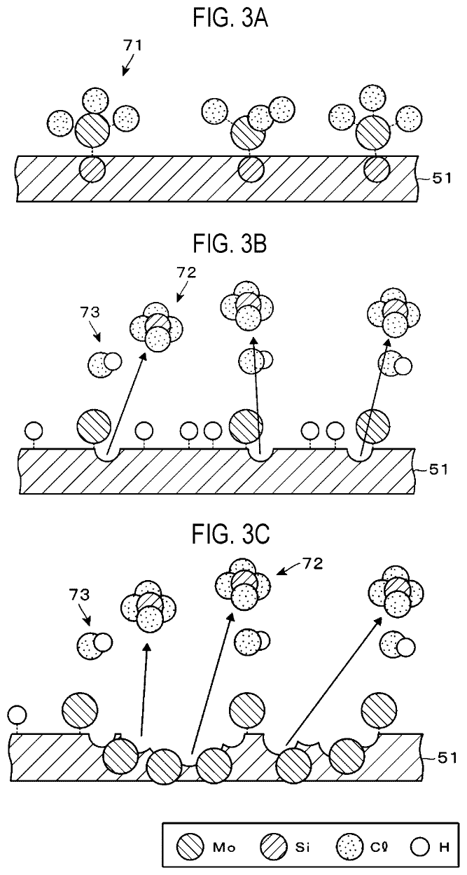

First, referring to the reaction models shown in FIGS. 3A to 3C, problems in forming the Mo layer 6 under conditions in which the wafer W is heated to a relatively high temperature will be described. The relatively high temperature is, for example, 490 degrees C. or higher, particularly 550 degrees C. or higher. When MoCl₅ gas is supplied to the silicon layer 51 exposed on the surface of the wafer W, MoClₓ 71 bonds to Si, as shown in FIG. 3A. Next, when H₂ gas is supplied, the MoClₓ 71 bonded to Si reacts with H₂ to form SiCl₄ 72 and HCl 73, and Mo atoms constituting the MoClₓ 71 remain on the silicon layer 51 (FIG. 3B).

These reactions may be expressed as the following overall reaction equation (1) (which indicates the stoichiometric ratio when, for example, X=5).

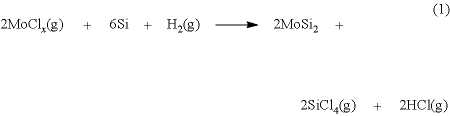

According to equation (1) above, as the deposition of Mo on the silicon layer 51 proceeds, etching in which the Si constituting the silicon layer 51 is released as a gas proceeds (FIG. 3C). As a result, a surface of the silicon layer 51 below the Mo layer 6 shown in FIG. 2 may become rough, and the contact resistance between the silicon layer 51 and a molybdenum silicide (MoSi) layer formed from the Mo layer 6 may increase.

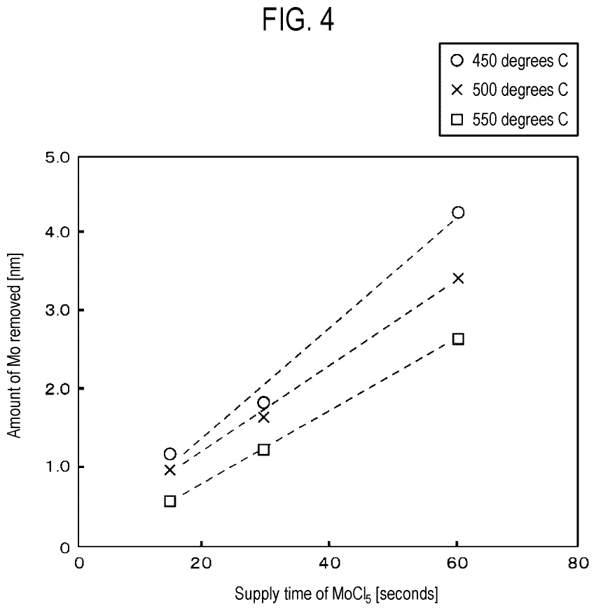

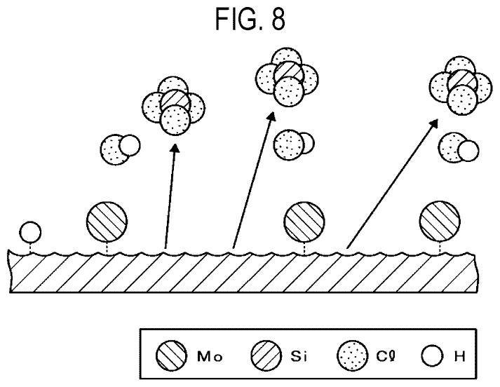

Therefore, a method of forming the Mo layer 6 by a reaction mechanism different from that of equation (1) may be considered. This may be achieved by limiting the heating temperature of the wafer W to, for example, 510 degrees C. or less, particularly 500 degrees C. or less (details of which will be described later with reference to FIG. 8). However, as shown in FIG. 4, it was found that MoCl₅, which is the raw material of the Mo layer 6, also acts as an etching gas for Mo.

The horizontal axis of FIG. 4 indicates supply time of MoCl₅ gas [seconds] supplied to the Mo substrate, and the vertical axis indicates an amount of Mo removed [nm]. According to FIG. 4, the longer the supply time of MoCl₅ gas, the greater the amount of Mo removed. It was also found that the lower the heating temperature of the Mo substrate, the greater a degree of increase in the amount of Mo removed. Even when MoCl₅ gas is used as the raw material gas, the Mo formed may be etched, which makes it difficult to efficiently form the Mo layer 6. In light of the problems described using FIGS. 3A to 3C and FIG. 4, in each embodiment described below, the specifics of the process of forming the Mo layer 6 are made different depending on the heating temperature of the wafer W.

### First Embodiment

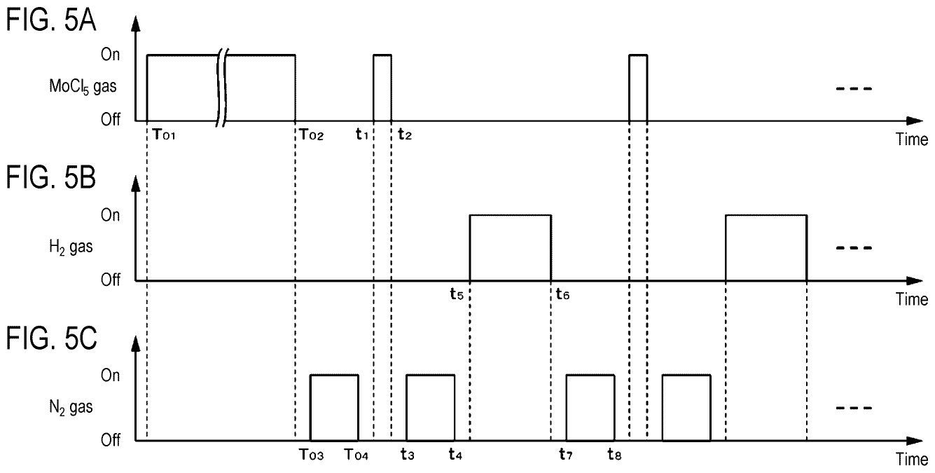

A first embodiment is applied to a case where the wafer W is heated to a temperature in a range of 490 degrees C. or higher and 600 degrees C. or lower. In the first embodiment, a preliminary supply in which a highly concentrated raw material gas is supplied to the wafer W, is performed before the formation of the Mo layer 6 by thermal ALD. FIGS. 5A to 5C are time charts showing an example of a supply sequence of various gases (raw material: MoCl₅ gas, reactive gas: H₂ gas, and purge gas: N₂) involved in the formation process of the Mo layer 6, which is performed using the above-mentioned processing apparatus 1. These time charts schematically show timings at which the various gases are supplied to the processing container 10 and cut off from being supplied.

In the time charts of FIGS. 5A to 5C, a preliminary supply of MoCl₅ gas is performed during a period from T₀₁ to T₀₂. The supply time of MoCl₅ gas in the preliminary supply is longer than the supply time of MoCl₅ gas (the period from t₁ to t₂ in FIGS. 5A to 5C) during each cycle of thermal ALD in which MoCl₅ gas and H₂ gas are alternately supplied. The supply time of MoCl₅ gas in the preliminary supply is, for example, 30 seconds, within a range of 5 seconds or more and 90 seconds or less. On the other hand, the supply time of MoCl₅ gas during each cycle of thermal ALD is, for example, 0.5 second, within a range of 0.1 second or more and 1 second or less.

Pressure in the processing container 10 is made higher during preliminary supply than during thermal ALD, by the pressure regulation valve of the exhauster 13. Thus, in the preliminary supply, a highly concentrated MoCl₅ gas is supplied to the wafer W. The pressure in the processing container 10 (processing atmosphere for the wafer W) during the preliminary supply is, for example, 5.33 kPa (40 Torr) within a range of 1.33 kPa or more and 5.33 kPa or less (10 Torr or more and 40 Torr or less). On the other hand, the pressure in the processing container 10 during the period in which thermal ALD is performed is, for example, 200 Pa (1.5 Torr) within a range of 133.3 Pa or more and 266.6 Pa or less (1.0 Torr or more and 2.0 Torr or less).

The controller 100 controls the supply and cut-off of each gas, and executes the supply of various gases based on the time charts shown in FIGS. 5A to 5C. That is, the controller 100 controls opening and closing of the valves V41, V42 and V43, executes the supply and cut-off of each gas, and sets flow rates of the flow rate adjusters M41, M42 and M43.

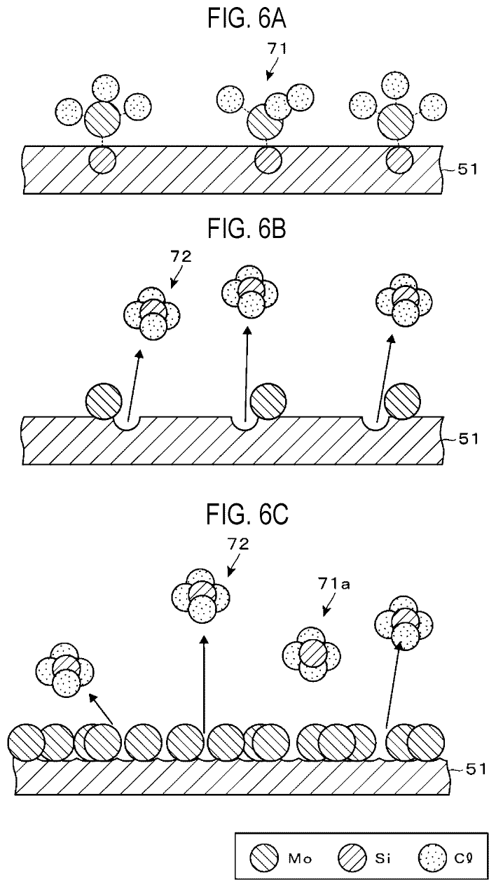

The process of forming the Mo layer 6 will be described with reference to the time charts of FIGS. 5A to 5C and the reaction model of FIGS. 6A to 6C. In the processing apparatus 1, first, the gate valve 15 is opened, and the wafer W is loaded into the processing container 10 through the loading/unloading port 14 by the transfer mechanism provided in the vacuum transfer chamber (not shown). The loaded wafer W is transferred from the transfer mechanism to the stage 2 via the lift pins (not shown) and placed on an upper surface of the stage 2. Next, the transfer mechanism is withdrawn from the processing container 10, and the gate valve 15 is closed. Then, the processing container 10 is evacuated by the exhauster 13, and the pressure in the processing container 10 is adjusted to the pressure at which the preliminary supply of MoCl₅ gas is performed. In addition, the heater 20 heats the wafer W to 550 degrees C., which is within the range of 490 degrees C. or higher and 600 degrees C. or lower (a process of heating the wafer W).

Thereafter, at time T₀₁ shown in FIGS. 5A to 5C, the preliminary supply of MoCl₅ gas is started. In this manner, the preliminary supply of MoCl₅ gas is performed for a preset time (e.g., 30 seconds) until time T₀₂ shown in FIGS. 5A to 5C (a process of preliminary supply of MoCl₅ gas). As shown in FIG. 6A, the supply of MoCl₅ gas during the preliminary supply period causes MoClₓ 71 to bond with Si, which is similar to the supply of MoCl₅ gas during the thermal ALD described with reference to FIG. 3A.

During the preliminary supply period, the reaction of the following equation (2) proceeds on the surface of the wafer W due to a thermal reaction, and Mo can be precipitated on the surface of the silicon layer 51 (FIG. 6B).

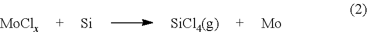

On the other hand, as described with reference to FIG. 4, MoCl₅ gas has an effect of etching Mo, and the reaction of the following equation (3) proceeds at the same time.

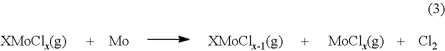

However, as described with reference to FIG. 4, regarding the effect of MoCl₅ gas to etch Mo, the higher the heating temperature of the wafer W, the smaller the degree of increase in the amount of Mo removed with respect to an increase in the supply time of MoCl₅ gas. Therefore, in the range of 490 degrees C. or higher and 600 degrees C. or lower, it is understood that, in terms of a balance between the precipitation of Mo by the reaction of equation (2) and the etching of Mo by the reaction of equation (3), the precipitation of Mo can be made dominant. Accordingly, it is possible to cover the surface of the silicon layer 51 with Mo, as shown in FIG. 6C.

When the surface of the silicon layer 51 is covered with Mo, the etching of Si described with reference to FIG. 3C and equation (1) is not likely to proceed even if H₂ gas is supplied. Therefore, by covering the surface of the silicon layer 51 with Mo by the preliminary supply of MoCl₅ gas, and then performing thermal ALD using MoCl₅ gas and H₂ gas, a Mo layer 6 having a sufficient thickness can be formed (a process of forming a Mo layer 6 on the surface of the silicon layer 51).

Therefore, for example, after the preliminary supply is performed for the aforementioned 30 seconds, the supply of MoCl₅ gas is stopped, and N₂ gas is supplied during a period from T₀₃ to T₀₄ to purge the inside of the processing container 10. At this time, the pressure in the processing container 10 is adjusted to the pressure at which the thermal ALD is performed.

Thereafter, one cycle of “supply of MoCl₅ gas for a period from t₁ to t₂→supply of N₂ gas (purging) for a period from t₃ to t₄→supply of H₂ gas for a period from t₅ to t₆→supply of N₂ gas (purging) for a period from t₇ to t₈” as shown in FIGS. 5A to 5C is repeated, for example, several tens to several hundred times to form a Mo layer 6 having a desired thickness. The supply period of H₂ gas (the period from t₅ to t₆) may be, for example, about 10 times the supply period of MoCl₅ gas (the period from t₁ to t₂).

When the Mo layer 6 is formed by the thermal ALD method, silicon is diffused from the silicon layer 51 into the Mo layer 6 to form a molybdenum silicide layer. In this regard, crystal structures of MoSi include a hexagonal crystal (h-MOSi₂, resistivity: 409 μΩ-cm) and a tetragonal crystal (t-MOSi₂, resistivity: 60 μΩ-cm). As shown in experimental results described later, it has been found that, when the preliminary supply of MoCl₅ gas is performed and the heating temperature of the wafer W is adjusted to fall within the range of 490 degrees C. or higher and 600 degrees C. or lower, it is possible to form a Mo layer 6 containing a tetragonal crystal having a low resistivity.

After a preset number of cycles have been performed in this manner, the heating of the wafer W is stopped. After purging the inside of the processing container 10, the vacuum evacuation is stopped, and the gate valve 15 is opened to allow the external transfer mechanism to enter. The wafer W is then unloaded in a reverse order of the loading.

According to the processing apparatus 1 of the first embodiment described above, MoCl₅ gas can be supplied to the wafer W including the exposed silicon layer 51, to form the Mo layer 6. In particular, by performing the preliminary supply of MoCl₅ gas, it is possible to create a state in which the surface of the silicon layer 51 is covered with Mo. After the surface of the silicon layer 51 is covered with Mo, the etching of Si based on equation (1) is not likely to proceed. Therefore, the Mo layer 6 can be formed while suppressing roughness of the surface of the silicon layer 51.

### Second Embodiment

A second embodiment is applied to a case in which the wafer W is heated to a temperature in the range of 400 degrees C. or higher and 510 degrees C. or lower. As described with reference to FIG. 4, the effect of MoCl₅ gas to etch Mo is such that the degree of increase in the amount of Mo removed with respect to an increase in the supply time of MoCl₅ gas tends to increase as the heating temperature of the wafer W decreases. Therefore, in the range of 400 degrees C. or higher and 510 degrees C. or lower, it is difficult to precipitate Mo or it takes time to cover the surface of the silicon layer 51, in terms of the balance between the precipitation of Mo by the reaction of the above-mentioned equation (2) and the etching of Mo by the reaction of the above-mentioned equation (3). Therefore, as in the first embodiment described with reference to FIG. 6C, it may be difficult to adopt the method of covering the surface of the silicon layer 51 with Mo by the preliminary supply of MoCl₅ gas and then performing the thermal ALD.

On the other hand, the deposition of Mo and the etching of Si based on equation (1) described with reference to FIGS. 3A to 3C are more likely to proceed as the heating temperature of the wafer W increases. When the wafer W is heated to a relatively high temperature of, for example, 490 degrees C. or higher, particularly 550 degrees C. or higher, a growth rate of the Mo layer 6 can be increased, but the roughness of the silicon layer 51 also increases. In contrast, when the wafer W is heated to a relatively low temperature of, for example, 510 degrees C. or lower, particularly 450 degrees C. or lower, the growth rate of the Mo layer 6 is low, but the roughness of the silicon layer 51 can also be suppressed to a low level. In the above description, the overlapping range of 490 degrees C. or higher and 510 degrees C. or lower, is a temperature range in which the growth rate of the Mo layer 6 and the roughness of the silicon layer 51 are moderate. Such overlapping range is a heating temperature range in which either method can be adopted, depending on the allowable roughness of the silicon layer 51 and the growth rate required for the Mo layer 6.

Therefore, for example, if the thickness of the Mo layer 6 to be formed is within a range of, for example, 0.5 nm to 10 nm, the heating temperature of the wafer W is limited to 400 degrees C. or higher and 510 degrees C. or lower. Thus, even without the preliminary supply of MoCl₅ gas, the Mo layer 6 can be formed while suppressing the roughness of the surface of the silicon layer 51.

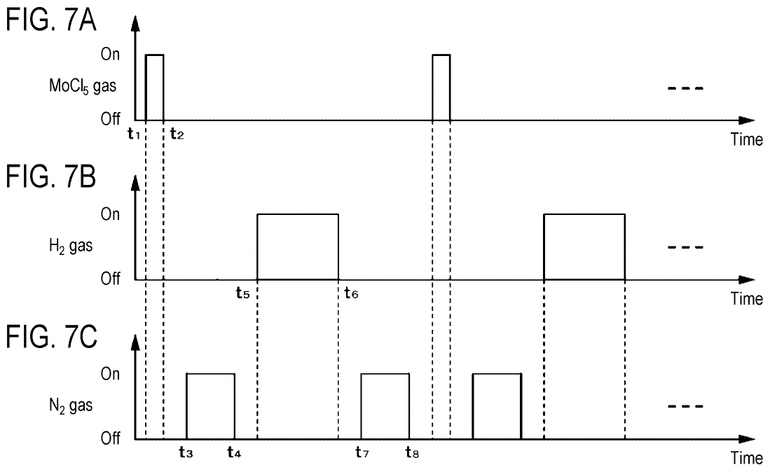

FIGS. 7A to 7C are time charts showing an example of a supply sequence of various gases according to a second embodiment. According to these time charts, thermal ALD is performed in the same manner as in the example described with reference to FIGS. 5A to 5C, except that the preliminary supply of MoCl₅ gas in the period from T₀₁ to T₀₂ and the purging by supplying the N₂ gas in the period from T₀₃ to T₀₄ are omitted. Except for the above-mentioned differences, the operation of the processing apparatus 1 is also the same as that of the first embodiment. Therefore, repeated descriptions will be omitted.

Accordingly, just like the reaction model described with reference to FIGS. 3A and 3B, even when the etching of the silicon layer 51 based on equation (1) proceeds, the degree of etching can be kept small, and molybdenum for forming the Mo layer 6 on the surface of silicon layer 51 can be precipitated (FIG. 8).

In the first and second embodiments described above, the Mo layer 6 is formed using MoCl₅ gas as the raw material gas and H₂ gas as the reactive gas. However, the metal of which the metal silicide is to be formed is not limited to this example. For example, TiCl₄, WCl₅, WCl₆, or the like may be used as the metal halide gas and may react with H₂ gas as the reactive gas to form a metal layer such as a Ti layer or a W layer.

In addition, the method of forming the metal layer such as the Mo layer 6 is not limited to the case of adopting the thermal ALD in which the raw material gas and the reactive gas are alternately supplied. For example, the raw material gas and the reactive gas may be simultaneously supplied to the heated wafer W, or a mixed gas of the raw material gas and the reactive gas may be supplied to deposit Mo, which is a reaction product, on the wafer W. In this case as well, when the heating temperature of the wafer W is in the range of 490 degrees C. or higher and 600 degrees C. or lower, a preliminary supply is performed to supply only the raw material gas. On the other hand, when the heating temperature of the wafer W is in the range of 400 degrees C. or higher and 510 degrees C. or lower, the formation of the Mo layer 6 is started without the preliminary supply.

Furthermore, the configuration of the apparatus for forming the Mo layer 6 is not limited to the example shown in FIG. 1. For example, a batch-type film forming apparatus may be used to simultaneously form films on a plurality of wafers W. In this case as well, as described with reference to FIGS. 5A to 5C and FIGS. 7A to 7C, the specifics of the process for forming the Mo layer 6 vary depending on the heating temperature of the wafer W. Thus, the Mo layer 6 can be formed while suppressing the roughness of the surface of the silicon layer 51.

The embodiments disclosed herein should be considered to be exemplary and not limitative in all respects. The above-described embodiments may be omitted, substituted, or modified in various forms without departing from the scope and spirit of the appended claims.

### Examples

### Experiment

Using the processing apparatus 1, a Mo layer 6 was formed on the surface of a silicon wafer W by a thermal ALD method. Effects of the heating temperature of the wafer W and whether or not a preliminary supply was performed were checked.

### A. Experimental Conditions

(Example 1-1) The preset temperature of the heater 20 of the stage 2 was 450 degrees C. The supply times of MoCl₅ gas, N₂ gas, H₂ gas, and N₂ gas were set to 0.1 second, 0.3 second, 3.0 seconds, and 0.4 second, respectively. Thermal ALD was performed by executing a cycle of these gas supplies 265 times. A mass flow rate of MoCl₅ contained in the raw material gas was 300 mg/min, and a supply flow rate of H₂ gas was 10 L/min (based on 0 degrees C. and 1 atm). The pressure in the processing container 10 was set to a high pressure of 5.33 kPa (40 Torr) (stress test). No preliminary supply of MoCl₅ gas was performed.

(Example 1-2) A Mo layer 6 was formed under the same conditions as in Example 1-1, except that the preset temperature of the heater 20 was 500 degrees C.

(Comparative Example 1-3) A Mo layer 6 was formed under the same conditions as in Example 1-1, except that the preset temperature of the heater 20 was 550 degrees C.

(Reference Example 2-1) A Mo layer 6 was formed under the same conditions as in Example 1-1, except that a preliminary supply of a MoCl₅ gas was performed for 60 seconds before performing thermal ALD. The pressure in the processing container 10 and the supply flow rate of MoCl₅ gas during the preliminary supply period were the same as when performing the thermal ALD.

(Example 2-2) A Mo layer 6 was formed under the same conditions as in Reference Example 2-1, except that the preset temperature of the heater 20 was 500 degrees C.

(Example 2-3) A Mo layer 6 was formed under the same conditions as in Reference Example 2-1, except that the preset temperature of the heater 20 was 550 degrees C.

### B. Experimental Results

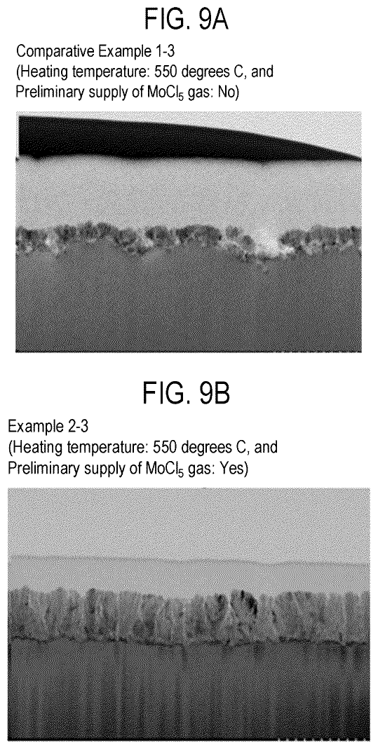

Enlarged microscopic photographs taken by a TEM (Transmission Electron Microscopy) for Comparative Example 1-3 and Example 2-3, in which the heating temperature of the wafer W was 550 degrees C., are shown in FIGS. 9A and 9B, respectively. In Comparative Example 1-3, in which the preliminary supply of MoCl₅ gas was not performed, the average thickness of the Mo layer 6 was 50 nm (FIG. 9A). It can also be seen that the surface of the silicon layer 51 below the Mo layer 6 was significantly roughened. On the other hand, in Example 2-3, in which the preliminary supply of MoCl₅ gas was performed, the average thickness of the Mo layer 6 was 150 nm (FIG. 9B). No significant roughness was observed on the surface of the silicon layer 51 below the Mo layer 6.

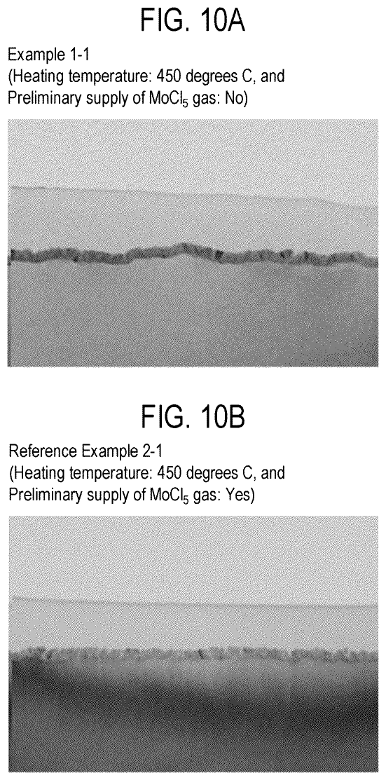

Next, enlarged microscopic photographs taken by a TEM for Example 1-1 and Reference Example 2-1, in which the heating temperature of the wafer W was 450 degrees C., are shown in FIGS. 10A and 10B, respectively. In Example 1-1, in which the preliminary supply of MoCl₅ gas was not performed, the average thickness of the Mo layer 6 was 40 nm (FIG. 9A). Moreover, no significant roughness was observed on the surface of the silicon layer 51 below the Mo layer 6 as in Comparative Example 1-3. On the other hand, in Reference Example 2-1, in which the preliminary supply of MoCl₅ gas was performed, the average thickness of the Mo layer 6 was 38 nm, and the growth rate of the Mo layer 6 was smaller than that of Example 2-3 (FIG. 10B). This is considered to be due to the fact that, despite the preliminary supply of MoCl₅ gas, the Mo precipitated by the preliminary supply was removed by etching with MoCl gas, and the fact that the growth rate of the Mo layer 6 was reduced due to the low heating temperature of the wafer W. No significant roughness was observed on the surface of the silicon layer 51 below the Mo layer 6.

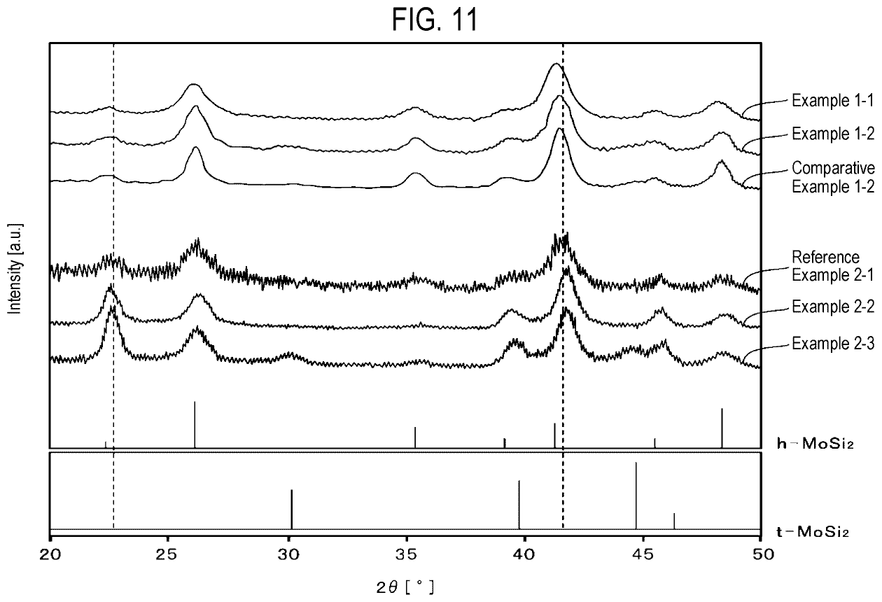

FIG. 11 shows results of XRD (X-Ray Diffraction) analysis for the Mo layers 6 formed in the Examples, Comparative Examples and Reference Examples. The Mo layers 6 were left for about 72 hours after being formed, and then analyzed. In all experimental results, the formation of molybdenum silicide (MoSi₂) was confirmed. Moreover, in Examples 1-1 and 1-2 and Comparative Example 1-3, in which the preliminary supply of MoCl₅ gas was not performed, the MoSi₂ formed was a hexagonal crystal (h-MOSi₂) having a high resistivity, regardless of the heating temperature of the wafer W. A tetragonal crystal (t-MOSi₂) having a low resistivity was hardly observed.

In contrast, in Reference Example 2-1 and Examples 2-2 and 2-3 in which the preliminary supply of MoCl₅ gas was performed, as the heating temperature of the wafer W increased, a peak in the diffraction angle (2θ: about 23°) was observed, indicating the inclusion of t-MOSi₂ having a low resistivity.

According to the present disclosure in some embodiments, it is possible to form a metal silicide layer by supplying a metal halide gas to a substrate including an exposed silicon layer.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method for forming a metal silicide layer on a substrate, the method comprising:
heating the substrate from which a silicon layer is exposed to a temperature in a range of 490 degrees C. or higher and 600 degrees C. or lower;
preliminarily supplying a raw material gas, which is a metal halide gas containing a metal that constitutes the metal silicide and a halogen, to the heated substrate; and
forming a layer of the metal on a surface of the silicon layer by alternately and repeatedly supplying the raw material gas and a reactive gas, which reacts with the metal halide to obtain the metal, to the substrate to which the raw material gas has been preliminarily supplied,
wherein the metal silicide layer is formed by diffusing silicon from the silicon layer into the layer of the metal.

2. The method of claim 1, wherein a supply time of the raw material gas which has been preliminarily supplied is longer than a supply time of the raw material gas in each cycle of alternately supplying the raw material gas and the reactive gas.

3. The method of claim 2, wherein the supply time of the raw material gas which has been preliminarily supplied is in a range of 5 seconds or more and 90 seconds or less.

4. The method of claim 2, wherein the supply time of the raw material gas in each cycle of alternately supplying the raw material gas and the reactive gas is in a range of 0.1 second or more and 1 second or less.

5. The method of claim 1, wherein a pressure of a processing atmosphere in which the substrate is placed when the raw material gas is preliminarily supplied is higher than a pressure of a processing atmosphere in which the substrate is placed when the raw material gas and the reactive gas are alternately supplied.

6. The method of claim 5, wherein the pressure of the processing atmosphere in which the substrate is placed when the raw material gas is preliminarily supplied is in a range of 1.33 kPa or more and 5.33 kPa or less.

7. The method of claim 5, wherein the pressure of the processing atmosphere in which the substrate is placed when the raw material gas and the reactive gas are alternately supplied is in a range of 133.3 Pa or more and 266.6 Pa or less.

8. The method of claim 1, wherein the metal is molybdenum, and the metal silicide is molybdenum silicide.

9. A method for forming a metal silicide layer on a substrate, the method comprising:
heating the substrate from which a silicon layer is exposed to a temperature in a range of 400 degrees C. or higher and 510 degrees C. or lower; and
forming a layer of the metal on a surface of the silicon layer by alternately supplying a raw material gas, which is a metal halide gas containing a metal that constitutes the metal silicide and a halogen, and a reactive gas, which reacts with the metal halide to obtain the metal, to the heated substrate,
wherein the metal silicide layer is formed by diffusing silicon from the silicon layer into the metal layer.

10. The method of claim 9, wherein a supply time of the raw material gas in each cycle of alternately supplying the raw material gas and the reactive gas is in a range of 0.1 second or more and 1 second or less.

11. The method of claim 9, wherein a pressure of a processing atmosphere in which the substrate is placed when the raw material gas and the reactive gas are alternately supplied is in a range of 133.3 Pa or more and 266.6 Pa or less.

12. The method of claim 9, wherein the metal is molybdenum, and the metal silicide is molybdenum silicide.

13. The method of claim 12, wherein the molybdenum silicide includes a tetragonal crystal.

14. The method of claim 12, wherein the raw material gas is a molybdenum pentachloride gas, and the reactive gas is a hydrogen gas.

15. An apparatus for forming a metal silicide layer on a substrate, comprising:
a processing container including a stage on which the substrate is placed, wherein a silicon layer is exposed from the substrate;
a heater configured to heat the substrate placed on the stage;
a raw material gas supply configured to supply a raw material gas, which is a metal halide gas containing a metal that constitutes the metal silicide and a halogen, into the processing container;
a reactive gas supply configured to supply a reactive gas, which reacts with the metal halide to obtain the metal, into the processing container; and
a controller,
wherein the controller is configured to output control signals to execute:
heating the substrate to a temperature in a range of 490 degrees C. or higher and 600 degrees C. or lower;
preliminarily supplying the raw material gas to the heated substrate; and
forming a layer of the metal on a surface of the silicon layer by alternately and repeatedly supplying the raw material gas and the reactive gas to the substrate to which the raw material gas has been preliminarily supplied, and
wherein the metal silicide layer is formed by diffusing silicon from the silicon layer into the layer of the metal.

16. The apparatus of claim 15, wherein the metal is molybdenum, and the metal silicide is molybdenum silicide.

17. An apparatus for forming a metal silicide layer on a substrate, comprising:
a processing container including a stage on which the substrate is placed, wherein a silicon layer is exposed from the substrate;
a heater configured to heat the substrate placed on the stage;
a raw material gas supply configured to supply a raw material gas, which is a metal halide gas containing a metal that constitutes the metal silicide and a halogen, to the processing container;
a reactive gas supply configured to supply a reactive gas, which reacts with the metal halide to obtain the metal, to the processing container; and
a controller,
wherein the controller is configured to output control signals to execute:
heating the substrate to a temperature in a range of 400 degrees C. or higher and 510 degrees C. or lower; and
forming a layer of the metal on a surface of the silicon layer by alternately and repeatedly supplying the raw material gas and the reactive gas to the heated substrate, and
wherein metal silicide layer is formed by diffusing silicon from the silicon layer into the layer of the metal.

18. The apparatus of claim 17, wherein the metal is molybdenum, and the metal silicide is molybdenum silicide.

19. The apparatus of claim 18, wherein the raw material gas is a molybdenum pentachloride gas, and the reactive gas is a hydrogen gas.
